(19) United States
(12) Patent Application Publication
(10) Pub. No.: US 2012/0298999 A1
(43) Pub. Date: Nov. 29, 2012

(54) SEMICONDUCTOR DEVICE AND MANUFACTURING METHOD THEREOF

(75) Inventors: Yasuhiro JINBO, Atsugi (JP); Koji DAIRIKI, Atsugi (JP); Hidekazu MIYAIRI, Atsugi (JP); Tomohiro KIMURA, Osaka (JP); Yoshitaka YAMAMOTO, Osaka (JP)

(73) Assignees: SHARP KABUSHIKI KAISHA, Osaka (JP); SEMICONDUCTOR ENERGY LABORATORY CO., LTD., Atsugi-shi (JP)

(21) Appl. No.: 13/477,353

(22) Filed: May 22, 2012

(30) Foreign Application Priority Data
May 24, 2011 (JP) 2011-116173

(51) Int. Cl. H01L 29/786; H01L 21/336

(52) U.S. Cl. 257/57; 438/151; 257/E21.412; 257/E29.289

(57) ABSTRACT

An object is to reduce off-state leakage current between a source electrode and a drain electrode. One embodiment of the present invention is a semiconductor device including a gate electrode, gate insulating films and formed to cover the gate electrode, an active layer formed over the gate insulating films and located above the gate electrode, silicon layers and formed over side surfaces of the active layer and the gate insulating films, and a source electrode and a drain electrode formed over the silicon layers. The active layer is not in contact with each of the source electrode and the drain electrode.

### BACKGROUND OF THE INVENTION

1. Field of the Invention

The present invention relates to a semiconductor device including a microcrystalline silicon film and a manufacturing method thereof and a thin film transistor including a microcrystalline silicon film and a manufacturing method thereof. Note that in this specification, a semiconductor device refers to a semiconductor element itself or a device including a semiconductor element. As an example of such a semiconductor element, for example, a transistor (a thin film transistor and the like) can be given. In addition, a semiconductor device also refers to a display device such as a liquid crystal display device.

2. Description of the Related Art

A thin film transistor in which microcrystalline silicon is used for an active layer (hereinafter referred to as “μCC TFT”) has higher field-effect mobility than a thin film transistor in which amorphous silicon is used for an active layer (hereinafter referred to as “a-Si TFT”), and therefore enables high-speed operation of a liquid crystal display panel when applied to a pixel TFT thereof. Meanwhile, recent liquid crystal displays have come to have higher resolution as well as higher operation speed. Such a high-resolution display panel including a large number of pixels is greatly affected by a load due to wiring resistance and parasitic capacitance between wirings and a load due to parasitic capacitance between a gate wiring and each of a source wiring and a drain wiring and between a gate electrode and each of a source electrode and a drain electrode. Therefore, it is difficult to achieve both high resolution and high-speed operation only by increasing the field-effect mobility of a pixel TFT.

In addition, the off-state leakage current of a pixel TFT of a liquid crystal display panel needs to be reduced. With large off-state leakage current, charge accumulated in a storage capacitor of a pixel circuit is released, whereby an electric field applied to a liquid crystal is weakened; thus, a desired contrast cannot be obtained.

When a μCC TFT has a structure (e.g., see Patent Document 1) in which a source electrode and a drain electrode are in contact with microcrystalline silicon (hereinafter referred to as “μc-Si”), leakage current (off-state leakage current) may be caused between the source electrode and the drain electrode even when the TFT is in an off state. Furthermore, since μc-Si has a band gap of about 1.1 eV, which is small as compared to 1.4 eV to 1.8 eV, the band gap of conventional amorphous silicon (hereinafter referred to as “a-Si”), the off-state leakage current is increased when a high temperature is applied to the μCC TFT or when the μc-Si of the μCC TFT is irradiated with light.

### REFERENCE

### Patent Document

[Patent Document 1] Japanese Published Patent Application No. 2009-021571 (FIGS. 3A and 3B)

### SUMMARY OF THE INVENTION

An object of one embodiment of the present invention is to reduce off-state leakage current between a source electrode and a drain electrode. Another object of one embodiment of the present invention is to reduce parasitic capacitance between a gate electrode and each of a source electrode and a drain electrode. Another object of one embodiment of the present invention is to reduce parasitic capacitance between a gate wiring and each of a source wiring and a drain wiring.

One embodiment of the present invention is a semiconductor device including a gate electrode, a gate insulating film formed to cover the gate electrode, an active layer formed over the gate insulating film and located above the gate electrode, a pair of silicon layers each formed over a side surface of the active layer and the gate insulating film, and a source electrode and a drain electrode formed over the pair of silicon layers. The active layer is not in contact with each of the source electrode and the drain electrode.

According to the above embodiment of the present invention, the pair of silicon layers are provided between the active layer and the source and drain electrodes, so that the source electrode and the drain electrode are not in contact with the active layer. With this structure, off-state leakage current between the source electrode and the drain electrode can be reduced when the transistor is in an off state.

In the above embodiment of the present invention, the gate insulating film and the pair of silicon layers are preferably formed between the source and drain electrodes and the gate electrode. With this structure, parasitic capacitance between the gate electrode and each of the source electrode and the drain electrode can be reduced.

In the above embodiment of the present invention, it is preferable that the gate insulating film include a silicon nitride film and a silicon oxide film formed over the silicon nitride film, the silicon oxide film be in contact with the active layer, and the silicon nitride film be in contact with the pair of silicon layers.

In the above embodiment of the present invention, it is preferable that the active layer include a microcrystalline silicon layer, the pair of silicon layers each include an amorphous silicon layer and an impurity silicon layer formed over the amorphous silicon layer, and the amorphous silicon layer be in contact with at least a side surface of the microcrystalline silicon layer and the gate insulating film.

In the above embodiment of the present invention, it is preferable that an insulating film be formed over the active layer and the pair of silicon layers each be formed on at least a side surface of the insulating film.

The above embodiment of the present invention can further include an insulating film formed over the active layer, the source electrode, the drain electrode, and the pair of silicon layers; and a back gate electrode formed over the insulating film and located above the active layer.

One embodiment of the present invention is a method for manufacturing a semiconductor device including the steps of forming a gate insulating film to cover a gate electrode, forming a microcrystalline silicon layer located above the gate electrode over the gate insulating film, forming a pair of amorphous silicon layers over the microcrystalline silicon layer and the gate insulating film, forming a pair of impurity silicon layers over the pair of amorphous silicon layers, and forming a source electrode and a drain electrode over the pair of impurity silicon layers. The pair of amorphous silicon layers are each formed under a condition where a crystal grows in a part of the amorphous silicon layer formed over the microcrystalline silicon layer and does not grow in a part of the amorphous silicon layer formed over the gate insulating film.

One embodiment of the present invention is a method for manufacturing a semiconductor device including the steps of forming a gate insulating film to cover a gate electrode; forming a microcrystalline silicon layer located above the gate electrode and a channel-stop film located above the microcrystalline silicon layer over the gate insulating film; forming a pair of amorphous silicon layers over the channel-stop film, the microcrystalline silicon layer, and the gate insulating film; forming a pair of impurity silicon layers over the pair of amorphous silicon layers; forming a conductive film over the pair of impurity silicon layers; and forming a source electrode and a drain electrode using the conductive film by etching the conductive film, the pair of impurity silicon layers, and the pair of amorphous silicon layers with the microcrystalline silicon layer protected by the channel-stop film. The pair of amorphous silicon layers are each formed under a condition where a crystal grows in a part of the amorphous silicon layer formed over the microcrystalline silicon layer and does not grow in a part of the amorphous silicon layer formed over the gate insulating film.

In the above embodiment of the present invention, it is preferable that a silicon nitride film be formed to cover the gate electrode and a silicon oxide film be formed over the silicon nitride film in the formation of the gate insulating film, the silicon oxide film be formed in contact with the microcrystalline silicon layer, and the silicon nitride film be formed in contact with the pair of amorphous silicon layers.

One embodiment of the present invention is a semiconductor device including a gate wiring; a first insulating film formed to cover the gate wiring; an active layer formed over the first insulating film; a second insulating film formed over the active layer; a silicon layer formed over the second insulating film, the active layer, and the first insulating film; and a source wiring or a drain wiring formed over the silicon layer and intersecting with the gate wiring. The first insulating film, the active layer, the second insulating film, and the silicon layer are formed between the source wiring or the drain wiring and the gate wiring.

According to the above embodiment of the present invention, the first insulating film, the active layer, the second insulating film, and the silicon layer are formed between the gate wiring and the source wiring or the drain wiring, whereby parasitic capacitance between the gate wiring and the source wiring or the drain wiring can be reduced.

In the above embodiment of the present invention, it is preferable that the first insulating film include a silicon nitride film and a silicon oxide film formed over the silicon nitride film, the silicon oxide film be in contact with the active layer, and the silicon nitride film be in contact with the silicon layer.

In the above embodiment of the present invention, it is preferable that the active layer include a microcrystalline silicon layer, the silicon layer include an amorphous silicon layer and an impurity silicon layer formed over the amorphous silicon layer, and the amorphous silicon layer be in contact with at least a side surface of the microcrystalline silicon layer and the first insulating film.

According to one embodiment of the present invention, off-state leakage current between a source electrode and a drain electrode can be reduced. According to one embodiment of the present invention, parasitic capacitance between a gate electrode and each of a source electrode and a drain electrode can be reduced. According to one embodiment of the present invention, parasitic capacitance between a gate wiring and each of a source wiring and a drain wiring can be reduced.

### BRIEF DESCRIPTION OF THE DRAWINGS

FIG. 1 is a cross-sectional view of a bottom-gate TFT according to one embodiment of the present invention.

FIG. 2 is a cross-sectional view of a dual-gate TFT according to one embodiment of the present invention.

FIG. 3A is a top view of a bottom-gate TFT according to one embodiment of the present invention, and FIG. 3B is a cross-sectional view along line 3B-3B′ in FIG. 3A.

FIG. 4A is a top view of a wiring portion formed over the same substrate as the bottom-gate TFT illustrated in FIGS. 3A and 3B, and FIG. 4B is a cross-sectional view along line 4B-4B′ in FIG. 4A.

FIG. 5 is a cross-sectional view illustrating a method for manufacturing a bottom-gate TFT according to one embodiment of the present invention.

FIG. 6 is a cross-sectional view illustrating the method for manufacturing the bottom-gate TFT according to one embodiment of the present invention.

FIG. 7 is a cross-sectional view illustrating the method for manufacturing the bottom-gate TFT according to one embodiment of the present invention.

FIG. 8 is a cross-sectional view illustrating the method for manufacturing the bottom-gate TFT according to one embodiment of the present invention.

FIG. 9 is a cross-sectional view illustrating the method for manufacturing the bottom-gate TFT according to one embodiment of the present invention.

### DETAILED DESCRIPTION OF THE INVENTION

Hereinafter, embodiments of the present invention will be described in detail with reference to the accompanying drawings. However, the present invention is not limited to the following description and it is easily understood by those skilled in the art that the mode and details can be variously changed without departing from the scope and spirit of the present invention. Accordingly, the present invention should not be construed as being limited to the description of the embodiments below.

### Embodiment 1

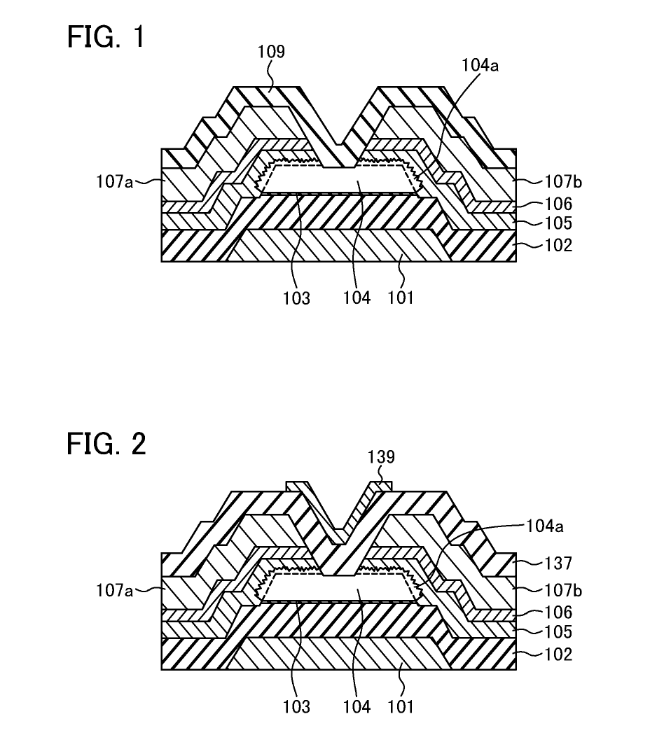

FIG. 1 is a cross-sectional view of a bottom-gate TFT according to one embodiment of the present invention. A gate electrode 101 is formed over a glass substrate (not shown). A first gate insulating film 102 is formed over the gate electrode 101 and the glass substrate, and a second gate insulating film 103 is formed over the first gate insulating film 102. The first gate insulating film 102 is preferably a silicon nitride film (hereinafter referred to as “SiNₓ film”) and the second gate insulating film 103 is preferably a silicon oxide film (hereinafter referred to as “SiOₓ film”), for example. Note that x>0.

A μc-Si layer 104 serving as an active layer located above the gate electrode 101 is formed over the first and second gate insulating films 102 and 103. The second gate insulating film 103 is located below the μc-Si layer 104. Over the μc-Si layer 104 and the first gate insulating film 102, a-Si layers 105 are formed as i-Si layers. Here, “i-Si” refers to intrinsic silicon to which no dopant, e.g., phosphorus (P), boron (B), and arsenic (As), is added. Note that nitrogen (N) may be added.

Over the a-Si layers 105, n⁺ Si layers 106 which are impurity silicon layers are formed. The n⁺ Si layers 106 are formed using a-Si to which phosphorus is added, μc-Si to which phosphorus is added, or the like. Alternatively, a stack of a-Si to which phosphorus is added and μc-Si to which phosphorus is added can be used for the n⁺ Si layers 106. In the case of forming a p-channel TFT as the TFT, the impurity silicon layers are formed using μc-Si to which boron is added, a-Si to which boron is added, or the like.

In other words, the a-Si layers 105 are formed between the μc-Si layer 104 and the n⁺ Si layers 106. The a-Si layers 105 are formed under a condition where the dilution ratio of hydrogen is high. In other words, the a-Si layers 105 are formed under a condition where a large amount of H₂ is used in a film formation gas (a high hydrogen dilution condition). Specifically, in a typical example of a condition for forming the a-Si layers 105, the flow rate of hydrogen is preferably about 10 times to 100 times that of a deposition gas containing silicon. For example, SiH₄:H₂ is preferably about 1:10 to 1:100. Thus, crystals grow (crystallization proceeds) in respective parts of the a-Si layers 105 in contact with the μc-Si layer 104 and crystals do not grow (crystallization does not proceed) in respective parts of the a-Si layers 105 in contact with a top surface of the first gate insulating film 102 (SiNₓ film). Consequently, crystalline regions 104a with a thickness in the range of 10 nm to 50 nm are formed in the respective parts of the a-Si layers 105 in contact with the μc-Si layer 104 (see FIG. 1).

A source electrode 107a and a drain electrode 107b are formed over the n⁺ Si layers 106. A protective insulating film 109 is formed over the source electrode 107a, the drain electrode 107b, and the μc-Si layer 104.

According to the bottom-gate TFT illustrated in FIG. 1, the a-Si layers 105 and the n⁺ Si layers 106 are provided between the μc-Si layer 104 and the source and drain electrodes 107a and 107b, so that the source electrode 107a and the drain electrode 107b are not in contact with the μc-Si layer 104. With this structure, leakage current (off-state leakage current) between the source electrode and the drain electrode can be reduced even when the TFT is in an off state.

In addition, the first gate insulating film 102, the a-Si layers 105, and the n⁺ Si layers 106 are provided between the gate electrode 101 and the source and drain electrodes 107a and 107b, so that parasitic capacitance between the gate electrode 101 and each of the source electrode 107a and the drain electrode 107b can be reduced.

FIG. 2 is a cross-sectional view of a dual-gate TFT according to one embodiment of the present invention. The same reference numerals are used for portions which are the same as those in FIG. 1, and only portions which are different from those in FIG. 1 will be described.

An insulating film 137 is formed over the μc-Si layer 104, the source electrode 107a, and the drain electrode 107b so as to cover the source electrode 107a and the drain electrode 107b. The insulating film 137 can be formed in a manner similar to that of the first gate insulating film 102.

A back gate electrode 139 is provided over the insulating film 137. The back gate electrode 139 can be formed in a manner similar to those of the gate electrode 101, the source electrode 107a, and the drain electrode 107b, but also can be formed using a light-transmitting conductive material. Note that the back gate electrode 139 is formed to overlap with a channel region in the μc-Si layer 104.

The back gate electrode 139 can be formed in parallel to the gate electrode 101. In this case, potential applied to the back gate electrode 139 and potential applied to the gate electrode 101 can be controlled independently. Thus, the threshold voltage of the TFT can be controlled. Further, regions in which carriers flow, that is, channel regions, are formed on the second gate insulating film 103 side and on the insulating film 137 side in the μc-Si layer 104; thus, the on-state current of the TFT can be increased.

The back gate electrode 139 may be connected to the gate electrode 101. That is, the gate electrode 101 and the back gate electrode 139 may be connected through an opening (not shown) formed in the first gate insulating film 102 and the insulating film 137. In this case, potential applied to the back gate electrode 139 and potential applied to the gate electrode 101 are equal. Therefore, regions in which carriers flow in the lac-Si layer 104, that is, channel regions are formed on the second gate insulating film 103 side and on the insulating film 137 side in the μc-Si layer 104; thus, the on-state current of the TFT can be increased.

Further alternatively, the back gate electrode 139 is not necessarily connected to the gate electrode 101 and may be in a floating state. In that case, channel regions are formed on the second gate insulating film 103 side and on the insulating film 137 side in the μc-Si layer 104 without a potential applied to the back gate electrode 139; thus, the on-state current of the TFT can be increased.

### Embodiment 2

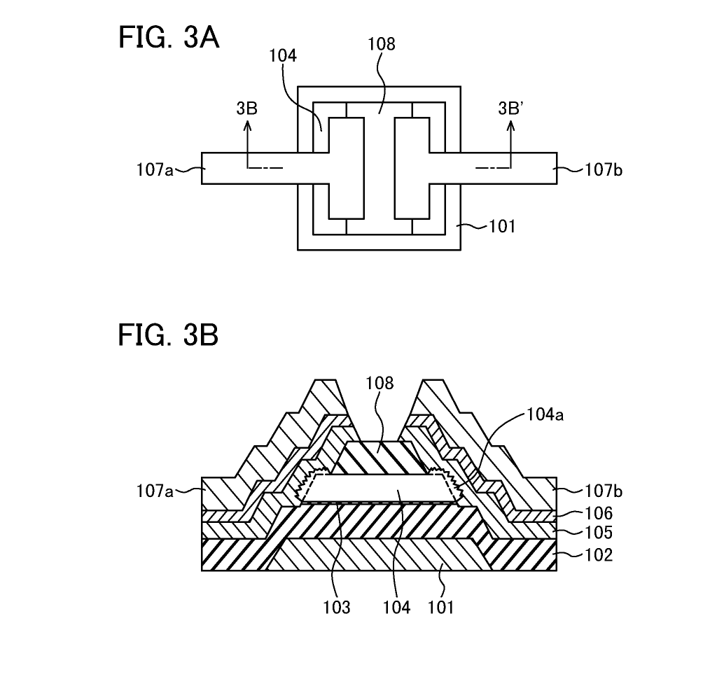

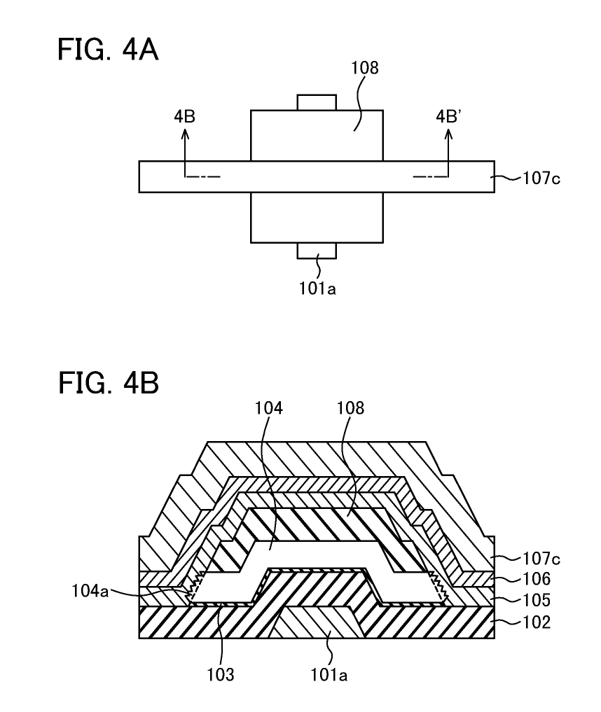

FIG. 3A is a top view of a bottom-gate TFT according to one embodiment of the present invention, and FIG. 3B is a cross-sectional view along line 3B-3B′ in FIG. 3A. FIG. 4A is a top view of a wiring portion formed over the same substrate as the bottom-gate TFT illustrated in FIGS. 3A and 3B, and FIG. 4B is a cross-sectional view along line 4B-4B′ in FIG. 4A.

The bottom-gate TFT illustrated in FIGS. 3A and 3B is the same as the bottom-gate TFT illustrated in FIG. 1 except for including a channel-stop film (channel-protective film) 108. The channel-stop film 108 is located above the μc-Si layer 104 and located below the a-Si layers 105, and is provided to protect the μc-Si layer 104 from etching damage at the time of formation of the a-Si layers 105 and the n⁺ Si layers 106.

An effect similar to that obtained with the bottom-gate TFT illustrated in FIG. 1 can be obtained with the bottom-gate TFT illustrated in FIGS. 3A and 3B.

As illustrated in FIGS. 4A and 4B, a gate wiring 101a is formed over a glass substrate (not shown). A first gate insulating film 102 is formed over the gate wiring 101a and the glass substrate, and a second gate insulating film 103 is formed over the first gate insulating film 102. The first gate insulating film 102 is preferably a SiNₓ film and the second gate insulating film 103 is preferably a SiOₓ film, for example. Note that x>0.

A μc-Si layer 104 located above the gate wiring 101a is formed over the first and second gate insulating films 102 and 103. The second gate insulating film 103 is located below the μc-Si layer 104. A channel-stop film 108 is formed over the μc-Si layer 104, and an a-Si layer 105 is formed over the channel-stop film 108 and the first gate insulating film 102. Over the a-Si layer 105, an n⁺ Si layer 106 is formed.

The a-Si layer 105 is formed under a condition where the dilution ratio of hydrogen to a deposition gas is high. Thus, crystals grow (crystallization proceeds) in parts of the a-Si layer 105 in contact with the μc-Si layer 104 and crystals do not grow (crystallization does not proceed) in parts of the a-Si layer 105 in contact with a top surface of the first gate insulating film 102 (SiNₓ film). Consequently, crystalline regions 104a with a thickness in the range of 10 nm to 50 nm are formed in the parts of the a-Si layer 105 in contact with the μc-Si layer 104 (see FIG. 4B). A wiring 107c serving as a source wiring or a drain wiring is formed over the n⁺ Si layer 106. The channel-stop film 108 is formed in a portion where the wiring 107c intersects with the gate wiring 101a to be interposed between the wirings (see FIGS. 4A and 4B).

According to the wiring portion illustrated in FIGS. 4A and 4B, the channel-stop film 108 is provided between the gate wiring 101a and the wiring 107c serving as a source wiring or a drain wiring, whereby parasitic capacitance between these wirings can be reduced. When this embodiment is applied to a high-resolution panel, parasitic capacitance between wirings can be reduced, which enables high-speed operation.

Note that a wiring portion having a structure in which the channel-stop film 108 is omitted from the wiring portion in FIGS. 4A and 4B may be employed as a modification example. An effect similar to that obtained with the wiring portion in FIGS. 4A and 4B can be obtained with this modification example.

### Embodiment 3

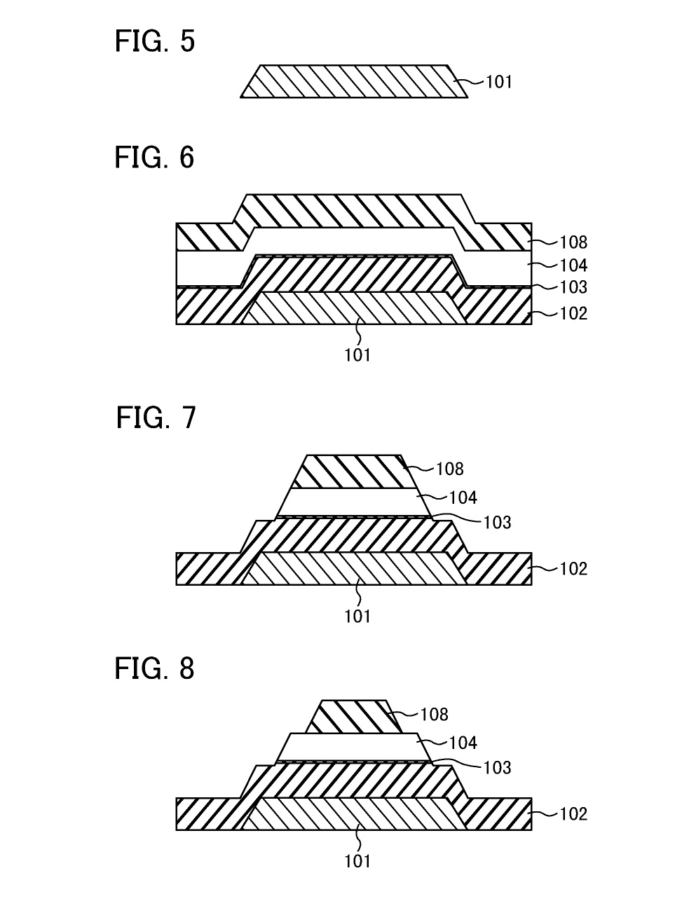

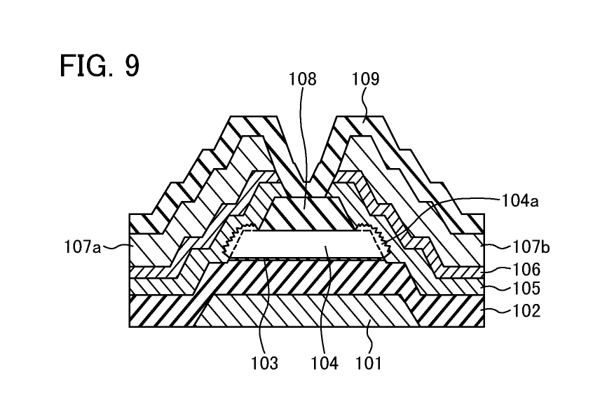

In this embodiment, a method for manufacturing a bottom-gate TFT according to one embodiment of the present invention will be described with reference to FIG. 5, FIG. 6, FIG. 7, FIG. 8, and FIG. 9.

As shown in FIG. 5, the gate electrode 101 is formed over a substrate (not shown). Specifically, a conductive film to be the gate electrode is formed over the substrate (not shown) with the use of a sputtering apparatus. Ti, Al, Mo, W, Cu, Cr, TiN, or the like or a stacked-layer structure of any of these may be used as the conductive film. For example, the conductive film may be a stacked-layer structure in which Ti, Al, and Ti are stacked in this order. Then, the conductive film is patterned to form the gate electrode 101 and a gate wiring (not shown). In order to improve adhesion between the gate electrode 101 and the substrate, a nitride film of any of the above-described metal materials may be provided between the substrate and the gate electrode 101. A transparent glass substrate, a ceramic substrate, or the like can be used as the substrate.

Side surfaces of the gate electrode 101 are preferably tapered. This is for the purpose of preventing a gate insulating film, a silicon film, and a wiring which are formed over the gate electrode 101 from being cut at a step portion of the gate electrode 101 in a later step. In order to taper the side surfaces of the gate electrode 101, etching may be performed while a resist mask is made to recede.

Next, as shown in FIG. 6, with the use of a plasma CVD apparatus, the first gate insulating film 102 covering the gate electrode 101 is formed, the second gate insulating film 103 is formed over the first gate insulating film 102, the μc-Si layer 104 serving as an active layer is formed over the second gate insulating film 103, and the channel-stop film 108 is formed over the μc-Si layer 104. A SiNₓ film can be used as the first gate insulating film 102 and a SiOₓ film can be used as the second gate insulating film 103. It is preferable that all the film formation be successively performed in a vacuum chamber of the plasma CVD apparatus because the μc-Si layer 104 is easily oxidized when exposed to the air. One vacuum chamber may be used or a plurality of vacuum chambers may be used.

The thickness of the SiOₓ film which is the second gate insulating film 103 is preferably less than or equal to 50 nm, further preferably less than or equal to 10 nm. Plasma oxidation treatment is performed after the formation of the SiNₓ film which is the first gate insulating film 102, whereby the SiOₓ film with a thickness of less than or equal to 10 nm can be formed over the first gate insulating film 102. For the plasma oxidation treatment, plasma of an oxidizing gas containing 0 such as N₂O, O₂, or H₂O, plasma of a mixed gas of an oxidizing gas and H₂, or plasma of a mixed gas of an oxidizing gas and a rare gas such as argon, helium, neon, or krypton may be used.

The degree of crystallization of the μc-Si layer 104 over the SiOₓ film can be higher than that of the μc-Si layer 104 over the SiNₓ film. The μc-Si layer 104 includes a first μc-Si layer and a second μc-Si layer formed over the first μc-Si layer.

A method for forming the first μc-Si layer and the second μc-Si layer will be described below in detail.

The first μc-Si layer includes mixed phase grains. It is preferable that the density of the mixed phase grains (existing percentage of the mixed phase grains in a plane) be low, the uniformity of grain sizes of the mixed phase grains be high, and the crystallinity of the mixed phase grains be high. Therefore, the first μc-Si layer may have space between the adjacent mixed phase grains without the adjacent mixed phase grains being in contact with each other. The thickness of the first μc-Si layer is preferably greater than or equal to 1 nm and less than or equal to 10 nm. In a region having the space between the adjacent mixed phase grains without the adjacent mixed phase grains being in contact with each other, the smallest height of the mixed phase grains which are not in contact with each other is preferably 1 nm or more and the largest height of the mixed phase grains which are not in contact with each other is preferably 10 nm or less. Note that the mixed phase grains each include an amorphous silicon region and a plurality of silicon crystallites that are microcrystals regarded as single crystals of silicon. In some cases, the mixed phase grains may include a twin crystal.

The first μc-Si layer is formed in a treatment chamber of a plasma CVD apparatus, using plasma generated by glow discharge with the use of a mixture of a deposition gas containing silicon and hydrogen as a source gas, under a first condition which allows mixed phase grains serving as nuclei to be formed in the state that the density of mixed phase grains is low and the crystallinity of the mixed phase grains is high. Alternatively, the first μc-Si layer is formed by glow discharge plasma with a mixture of a deposition gas containing silicon, hydrogen, and a rare gas such as helium, neon, or krypton. Here, the μc-Si is formed under the first condition in which the pressure inside the treatment chamber is higher than or equal to 67 Pa and lower than or equal to 50000 Pa (higher than or equal to 0.5 Ton and lower than or equal to 375 Ton).

The method for supplying the source gas under the first condition is such a method that a gas obtained by diluting the deposition gas containing silicon by setting the flow rate of hydrogen to be greater than or equal to 50 times and less than or equal to 1000 times that of the deposition gas is supplied. The deposition temperature is preferably from room temperature to 300° C., and further preferably 150° C. to 280° C. The distance between an upper electrode and a lower electrode of the plasma CVD apparatus may be set to a distance which allows generation of plasma.

Typical examples of the deposition gas containing silicon include SiH₄, Si₂H₆, and the like.

In the case where a rare gas such as helium, argon, neon, krypton, or xenon is mixed into the source gas of the first μc-Si layer, the deposition rate of the first μc-Si layer is increased. In addition, in the case where the deposition rate is increased, the amount of impurities mixed in the first μc-Si layer is reduced, so that the crystallinity of the first μc-Si layer can be improved. Thus, the on-state current and field-effect mobility of the TFT are increased and throughput of manufacturing the TFT can also be increased.

In the glow discharge at the time of forming the first μc-Si layer, the plasma is generated by application of high-frequency power with a frequency of 3 MHz to 30 MHz, typically 13.56 MHz or 27.12 MHz in the HF band, or high-frequency power with a frequency of approximately 30 MHz to 300 MHz in the VHF band, typically 60 MHz. It is preferable to determine the power for generating the plasma as appropriate in accordance with the ratio of the flow rate of hydrogen to the flow rate of the deposition gas containing silicon.

Next, the second μc-Si layer is formed over the first μc-Si layer. The second μc-Si layer includes mixed phase grains each including silicon crystallites and amorphous silicon, and is preferably formed under a condition which enables the second μc-Si layer to fill the space between the mixed phase grains of the first μc-Si layer and also promotes crystal growth. Note that the thickness of the second μc-Si layer is preferably greater than or equal to 30 nm and less than or equal to 100 nm.

The second μc-Si layer is formed in a treatment chamber of the plasma CVD apparatus, using plasma generated by glow discharge with the use of a mixture of a deposition gas containing silicon and hydrogen as a source gas under a second condition. Alternatively, the second μc-Si layer may be formed using plasma generated by glow discharge with the use of a mixture of a deposition gas containing silicon, hydrogen, and a rare gas such as helium, neon, or krypton under the second condition. Here, the μc-Si is formed under the second condition in which the deposition gas containing silicon is diluted by setting the flow rate of hydrogen to be greater than or equal to 100 times and less than or equal to 2000 times that of the deposition gas and the pressure inside the treatment chamber is set to be higher than or equal to 1333 Pa and lower than or equal to 50000 Pa (higher than or equal to 10 Torr and lower than or equal to 375 Torr). As a result, the ratio of a crystalline region to an amorphous semiconductor region is increased in the second μc-Si layer, whereby the crystallinity is increased. The deposition temperature at this time is preferably from room temperature to 300° C., and further preferably 150° C. to 280° C. The distance between an upper electrode and a lower electrode of the plasma CVD apparatus may be set to a distance which allows generation of plasma. By newly generating the mixed phase grains of the second μc-Si layer in the space between the mixed phase grains of the first μc-Si layer, the size of the mixed phase grains is reduced. Therefore, it is preferable that the frequency of generation of the mixed phase grains of the second μc-Si layer be lower than that of the mixed phase grains of the first μc-Si layer.

In the case where a rare gas such as helium, argon, neon, krypton, or xenon is mixed into the source gas of the second μc-Si layer, the crystallinity of the second μc-Si layer can be increased in a manner similar to that of the first μc-Si layer. Thus, the on-state current and the field-effect mobility of the TFT are increased and the throughput of manufacturing the TFT can also be increased.

The condition for generating plasma by glow discharge at the time of forming the first μc-Si layer can be employed as appropriate for formation of the second μc-Si layer. When plasma is generated by glow discharge under the same condition in forming the first μc-Si layer and the second μc-Si layer, throughput can be increased; however, different conditions may be employed.

The first μc-Si layer and the second μc-Si layer are formed using μc-Si. Note that μc-Si is a semiconductor having an intermediate structure between an amorphous structure and a crystalline structure (including a single crystal structure and a polycrystalline structure). Further, μc-Si is a semiconductor having a third state that is stable in terms of free energy and is a crystalline semiconductor having short-range order and lattice distortion, in which columnar or needle-like crystals having a mixed phase grain size of 2 nm to 200 nm, preferably 10 nm to 80 nm, further preferably 20 nm to 50 nm, still further preferably 25 nm to 33 nm have grown in a direction normal to the substrate surface. Therefore, there are some cases in which a crystal grain boundary is formed at the interface between the columnar or needle-like crystals. Note that the mixed phase grain size here means a maximum diameter of a mixed phase grain in a plane parallel to the substrate surface.

The Raman spectrum of μc-Si, which is a typical example, shifts to a lower wavenumber side than 520 cm⁻¹ which represents single crystal silicon. That is, the peak of the Raman spectrum of μc-Si exists between 520 cm⁻¹ which represents single crystal silicon and 480 cm⁻¹ which represents amorphous silicon. In addition, μc-Si includes at least 1 at. % or more of hydrogen or halogen to terminate a dangling bond. Further promotion of lattice distortion by inclusion of a rare gas element such as helium, argon, krypton, or neon can provide favorable μc-Si with increased stability. Such μc-Si is disclosed in U.S. Pat. No. 4,409,134, for example.

According to this embodiment, a μc-Si layer having high crystallinity with reduced space between mixed phase grains can be formed.

Further, with a two-step film formation method in which the second μc-Si layer is stacked over the first μc-Si layer, the space between the mixed phase grains can be effectively filled; consequently, a μc-Si layer having large grain size and high crystallinity as well as keeping high film density can be formed. As a result, the field-effect mobility can be increased, and a TFT with excellent electric characteristics can be provided.

In this embodiment, the two-step film formation method in which the second μc-Si layer is stacked over the first μc-Si layer is employed to form the μc-Si layer; however, the two-step film formation method is not a requisite and the μc-Si layer may be formed using a one-step film formation method or a three-step film formation method.

Alternatively, a cycle flow process can be employed for at least one of the method for supplying the source gas under the first condition and the method for supplying the source gas under the second condition in this embodiment. A case of employing a cycle flow process for the method for supplying the source gas under the first condition will be described below. The following description can also apply to a case of employing a cycle flow process for the method for supplying the source gas under the second condition.

The method for supplying the source gas under the first condition is as follows: supply of a gas obtained by diluting the deposition gas containing silicon by setting the flow rate of hydrogen to be greater than or equal to 50 times and less than or equal to 1000 times that of the deposition gas and supply of a gas in which the flow rate of the deposition gas is lower than that of the deposition gas in the gas supplied as above and is set so as to primarily cause etching of silicon deposited over the second gate insulating film than deposition of silicon over the second gate insulating film are alternately performed. Note that the flow rate of the deposition gas which primarily causes the etching may be 0 sccm. The deposition temperature at this time is preferably room temperature to 300° C., further preferably 150° C. to 280° C. The distance between an upper electrode and a lower electrode of the plasma CVD apparatus may be set to a distance which allows generation of plasma.

The method for supplying the source gas under the first condition is a method in which the flow rate of the deposition gas containing silicon is changed to alternate between high and low flow rates during generation of plasma by glow discharge. During the period in which the deposition gas is supplied at a low flow rate, etching of silicon deposited over the second gate insulating film primarily occurs rather than deposition of silicon over the second gate insulating film. In contrast, during the period in which the deposition gas is supplied at a high flow rate, deposition of silicon over the second gate insulating film primarily occurs rather than etching of silicon deposited over the second gate insulating film. Thus, an amorphous silicon component is selectively etched by the hydrogen gas during the period in which the deposition gas is supplied at a low flow rate, and the mixed phase grains grow during the period in which the deposition gas is supplied at a high flow rate. By the repetition of the etching and the growth, the first μc-Si layer including a small amount of amorphous silicon component and having high crystallinity can be obtained.

The supply of the deposition gas at a high flow rate enlarges the mixed phase grains that have already been deposited over the second gate insulating film and produces new mixed phase grains over the second gate insulating film. The supply of the deposition gas at a low flow rate causes etching and removal of the small mixed phase grains that have just been generated but leaves the relatively large mixed phase grains that have already been deposited over the second gate insulating film. By the repetition of the growth and the etching, the mixed phase grains with small grain sizes are reduced. Thus, the first μc-Si layer including many mixed phase grains having large and highly uniform grain sizes can be obtained.

With the first condition in this manner, crystal growth is promoted and the crystallinity of the mixed phase grains is increased. That is, the size of a crystallite included in the mixed phase grain is increased. Further, space is formed between the adjacent mixed phase grains, so that the density of the mixed phase grains is lowered.

The use of the above-described method for supplying the source gas in which the flow rate of the deposition gas is changed to alternate between high and low flow rates makes the grain size of the mixed phase grains deposited over the second gate insulating film large, the uniformity of the mixed phase grains high, and the crystallinity of the mixed phase grains high as compared to the case of supplying the deposition gas at a constant flow rate without the flow rate thereof changed.

As described above, at the time of forming the first μc-Si layer, the use of the supplying method of the source gas in which the flow rate of the deposition gas is changed to alternate between high and low flow rates makes the grain size of the mixed phase grains deposited over the second gate insulating film large and the crystallinity of the mixed phase grains high as compared to the case of supplying the deposition gas at a constant flow rate without the flow rate thereof changed. Further, with the two-step film formation method in which the second μc-Si layer is stacked over the first μc-Si layer, space between the mixed phase grains can be effectively filled; consequently, a μc-Si layer having large grain size and high crystallinity as well as keeping high film density can be formed. As a result, the field-effect mobility can be increased, and a TFT with excellent electric characteristics can be provided.

For the channel-stop film 108, a SiNₓ film or a stacked film in which a SiOₓ film and a SiNₓ film are stacked in this order may be used, for example. The thin film of SiOₓ in the stacked film may be formed by performing plasma oxidation treatment similar to that described above after the formation of the μc-Si layer.

Next, a first resist mask (not shown) is formed by a photolithography step. With the use of the first resist mask, the channel-stop film 108, the μc-Si layer 104, and the second gate insulating film 103 are etched. Thus, the μc-Si layer 104 serving as an active layer located above the gate electrode 101 is formed over the first and second gate insulating films 102 and 103 (see FIG. 7).

Next, a second resist mask (not shown) is formed by a photolithography step and the channel-stop film 108 is further etched with the use of the second resist mask, whereby the channel-stop film 108 is formed smaller than a top surface of the μc-Si layer 104 (see FIG. 8).

Note that with the use of a gray-tone (half-tone) mask, the first resist mask for processing the μc-Si layer 104 serving as an active layer and the second resist mask for processing the channel-stop film 108 can be formed with one mask. That is, the step shown in FIG. 7 and the step shown in FIG. 8 can be performed using one mask. Specifically, parts of the mask which cover areas where the μc-Si layer is to be exposed in the step in FIG. 8 are made semi-light-transmissive, a resist mask is formed over the channel-stop film 108 so that thin resist remains at the areas where the μc-Si layer is to be exposed, and the channel-stop film 108 and the μc-Si layer 104 are etched with the use of this resist mask (corresponding to the step in FIG. 7). Then, ashing is performed so that a resist mask whose resist is reduced until there is no resist in the area where the lac-Si layer is to be exposed is formed, and the channel-stop film 108 is etched using this resist mask (corresponding to the step in FIG. 8).

In this embodiment, the channel-stop film 108 is formed, but this embodiment can be implemented without forming the channel-stop film 108. Specifically, the first gate insulating film 102, the second gate insulating film 103, and the μc-Si layer 104 are formed in this order over the gate electrode 101; the channel-stop film 108 is not formed. Then, the μc-Si layer 104 and the second gate insulating film 103 are etched using a resist mask, whereby the μc-Si layer 104 serving as an active layer located above the gate electrode 101 is formed over the first and second gate insulating films 102 and 103. The following steps are performed similarly to those in this embodiment. In this manner, the TFT illustrated in FIG. 1 can be manufactured. Without the channel-stop film 108, when the n⁺ Si layer 106 and the a-Si layer 105 are etched together with a conductive film, described later, which is to be a source electrode and a drain electrode, a depression (a portion which is slightly etched at the time of forming a source and a drain) may be caused in the μc-Si layer 104 by over etching (see FIG. 1). Alternatively, in the etching of the n⁺ Si layer 106 and the a-Si layer 105, the etching may be stopped before the μc-Si layer 104 is exposed, so that the a-Si layer 105 remains, in which case a depression (portion which is slightly etched at the time of forming a source and a drain) is not caused in the μc-Si layer 104 (not shown).

Then, as shown in FIG. 9, the a-Si layer 105 serving as an i-Si layer and the n⁺ Si layer 106 are formed over the channel-stop film 108, the μc-Si layer 104, and the first gate insulating film 102 with the use of the plasma CVD apparatus. The a-Si layer 105 is formed as a buffer layer for reducing an off-state leakage current. The a-Si layer 105 is formed because an amorphous phase having a wide band gap is necessary in order to reduce an off-state leakage current.

The a-Si layer 105 and the n⁺ Si layer 106 are formed in a treatment chamber of the plasma CVD apparatus, using plasma generated by glow discharge with the use of a mixture of a deposition gas containing silicon and a gas containing hydrogen.

A condition where a large amount of H₂ is used in a film formation gas, i.e., a high hydrogen dilution condition is preferably used in order to obtain a favorable contact at the interface between the μc-Si layer 104 and the a-Si layer 105. Specifically, in a typical example of a condition for forming the a-Si layer 105, the flow rate of hydrogen is preferably about 10 times to 100 times that of the deposition gas containing silicon. For example, SiH₄:H₂ is preferably about 1:10 to 1:100. Note that in a typical example of a condition for forming a normal amorphous silicon film, the flow rate of hydrogen is 0 times to 5 times that of the deposition gas containing silicon.

Although an appropriate dilution ratio of hydrogen varies depending on a pressure, radio frequency (RF) power, temperature, or the like, the dilution ratio of hydrogen may be adjusted so that crystals grow in the region 104a of the a-Si layer 105, which has a thickness of about 10 nm to 50 nm (preferably 20 nm to 40 nm) and is formed over the μc-Si layer 104 serving as an active layer, and a region of the a-Si layer 105 other than the region 104a is amorphous, and so that crystals do not grow in parts of the a-Si layer 105 formed over the SiNₓ film that is the first gate insulating film 102. Thus, the regions 104a where crystals grow can be formed at the interface between the μc-Si layer 104 and the a-Si layer 105, and the a-Si layer 105 can be formed using a well-ordered silicon film having fewer defects and a steep tail of a level at a valence band edge.

The regions 104a where crystals grow have depressions and projections. The projection has a conical or pyramidal shape with a width decreasing from the μc-Si layer 104 toward the n⁺ Si layer 106 (a tip of the projection has an acute angle). Alternatively, the regions 104a where crystals grow may have a projection whose width increases from the μc-Si layer 104 toward the n⁺ Si layer 106 (an inverted conical or pyramidal shape).

Further, when crystals grow in the a-Si layer 105 over the first gate insulating film 102, crystals of the regions 104a grow in a region below which the gate electrode 101 is not provided; therefore, a large amount of off-state current leaks when light (light from a backlight unit for a liquid crystal display) is emitted from the substrate side. For this reason, the a-Si layer 105 may be formed with the use of a film formation gas in which a small amount of NH₃ is added in order to reduce excessive crystal growth of the a-Si layer 105 that is a buffer layer.

The n⁺ Si layer 106 is formed in a treatment chamber of the plasma CVD apparatus, using plasma generated by glow discharge with the use of a mixture of a deposition gas containing silicon, hydrogen, and phosphine (diluted with hydrogen or silane) as a source gas. Amorphous silicon to which phosphorus is added or microcrystalline silicon to which phosphorus is added is formed by diluting the deposition gas containing silicon with hydrogen.

Next, a conductive film to be the source electrode 107a, the drain electrode 107b, a source wiring (not shown), and a drain wiring (not shown) is formed with a sputtering apparatus, a CVD apparatus, or a vacuum evaporation apparatus. It is sufficient that the conductive film has a structure similar to that of the conductive film to be the gate electrode 101.

Next, a resist mask (not shown) is formed by a photolithography step and the conductive film is etched with the use of the resist mask. Thus, the source electrode 107a, the drain electrode 107b, the source wiring, and the drain wiring are formed. The source wiring and the drain wiring intersect with the gate wiring (see FIGS. 4A and 4B). The etching of the conductive film may be either dry etching or wet etching. At the time of etching the conductive film, the n⁺ Si layer 106 and the a-Si layer 105 are etched together with the conductive film. The μc-Si layer 104 serving as an active layer is not etched because the μc-Si layer 104 is protected by the channel-stop film 108.

Then, the protective insulating film (passivation film) 109 covering the exposed channel-stop film 108, the exposed n⁺ Si layers 106, the exposed a-Si layers 105, the source electrode 107a, and the drain electrode 107b is formed.

This application is based on Japanese Patent Application serial no. 2011-116173 filed with Japan Patent Office on May 24, 2011, the entire contents of which are hereby incorporated by reference.

What is claimed is:

1. A semiconductor device comprising:
a gate electrode;
a first gate insulating film over the gate electrode;
a microcrystalline silicon layer over the first gate insulating film;
a first amorphous silicon layer and a second amorphous silicon layer over the microcrystalline silicon layer, wherein each of the first amorphous silicon layer and the second amorphous silicon layer is in contact with the first gate insulating film;
a first n⁺ silicon layer over the first amorphous silicon layer;
a second n⁺ silicon layer over the second amorphous silicon layer;
a first electrode over the first n⁺ silicon layer; and
a second electrode over the second n⁺ silicon layer.

2. The semiconductor device according to claim 1, further comprising:
a first crystalline region between the microcrystalline silicon layer and the first amorphous silicon layer; and
a second crystalline region between the microcrystalline silicon layer and the second amorphous silicon layer.

3. The semiconductor device according to claim 1, wherein the first gate insulating film is a silicon nitride film.

4. The semiconductor device according to claim 1, further comprising a second gate insulating film between the first gate insulating film and the microcrystalline silicon layer.

5. The semiconductor device according to claim 4, wherein the second gate insulating film is a silicon oxide film.

6. The semiconductor device according to claim 1, wherein the first n⁺ silicon layer and the second n⁺ silicon layer each comprises an amorphous silicon or a microcrystalline silicon.

7. The semiconductor device according to claim 1, further comprising:
an insulating film over the first electrode and the second electrode; and
a backgate electrode over the microcrystalline silicon layer with the insulating film interposed therebetween.

8. A semiconductor device comprising:
a gate electrode;
a first gate insulating film over the gate electrode;
a microcrystalline silicon layer over the first gate insulating film;
a channel stop film over the microcrystalline silicon layer;
a first amorphous silicon layer and a second amorphous silicon layer over the channel stop film, wherein each of the first amorphous silicon layer and the second amorphous silicon layer is in contact with the first gate insulating film;
a first n⁺ silicon layer over the first amorphous silicon layer;
a second n⁺ silicon layer over the second amorphous silicon layer;
a first electrode over the first n⁺ silicon layer; and
a second electrode over the second n⁺ silicon layer.

9. The semiconductor device according to claim 8, further comprising:
a first crystalline region between the microcrystalline silicon layer and the first amorphous silicon layer; and
a second crystalline region between the microcrystalline silicon layer and the second amorphous silicon layer.

10. The semiconductor device according to claim 8, wherein the first gate insulating film is a silicon nitride film.

11. The semiconductor device according to claim 8, further comprising a second gate insulating film between the first gate insulating film and the microcrystalline silicon layer.

12. The semiconductor device according to claim 11, wherein the second gate insulating film is a silicon oxide film.

13. The semiconductor device according to claim 8, wherein the first n⁺ silicon layer and the second n⁺ silicon layer each comprises an amorphous silicon or a microcrystalline silicon.

14. A method for manufacturing a semiconductor device, the method comprising the steps of:
forming a gate electrode;
forming a first gate insulating film over the gate electrode;
forming a microcrystalline silicon film over the first gate insulating film;
forming a first insulating film over the microcrystalline silicon film;
forming a microcrystalline silicon layer and a second insulating film by removing part of the microcrystalline silicon film and part of the first insulating film, respectively;
forming a channel stop film by removing part of the second insulating film;
forming a amorphous silicon film over the channel stop film;
forming a n⁺ silicon film over the amorphous silicon film;
forming a conductive film over the n⁺ silicon film; and
forming a first stack of a first amorphous silicon layer, a first n⁺ silicon layer, and a first electrode and a second stack of a second amorphous silicon layer, a second n⁺ silicon layer, and a second electrode by removing part of the amorphous silicon film, part of the n⁺ silicon film, and part of the conductive film, respectively.

15. The method for manufacturing a semiconductor device according to claim 14,
wherein a first crystalline region is formed between the microcrystalline silicon layer and the first amorphous silicon layer, and
wherein a second crystalline region is formed between the microcrystalline silicon layer and the second amorphous silicon layer.

16. The method for manufacturing a semiconductor device according to claim 14, wherein the first gate insulating film is a silicon nitride film.

17. The method for manufacturing a semiconductor device according to claim 14, further comprising the step of forming a second gate insulating film between the first gate insulating film and the microcrystalline silicon layer.

18. The method for manufacturing a semiconductor device according to claim 17, wherein the second gate insulating film is a silicon oxide film.

19. The method for manufacturing a semiconductor device according to claim 14, wherein the first n⁺ silicon layer and the second n⁺ silicon layer each comprises an amorphous silicon or a microcrystalline silicon.
